(19) United States
(12) Patent Application Publication
(10) Pub. No.: US 2009/0206841 A1
(43) Pub. Date: Aug. 20, 2009

(54) INTELLIGENT FAULT-TOLERANT BATTERY MANAGEMENT SYSTEM

(76) Inventor: Sam WENG, Cupertino, CA (US)

Correspondence Address: SHEMWELL MAHAMEDI LLP, 4880 STEVENS CREEK BOULEVARD, SUITE 201, SAN JOSE, CA, 95129-1034, US

(21) Appl. No.: 12/372,704

(22) Filed: Feb. 17, 2009

Related U.S. Application Data
(60) Provisional application No. 61/029,300, filed on Feb. 15, 2008.
(60) Provisional application No. 61/029,296, filed on Feb. 15, 2008.
(60) Provisional application No. 61/029,302, filed on Feb. 15, 2008.

(51) Int. Cl. G01R 31/36; H02J 9/00

(52) U.S. Cl. 324/426; 307/64

(57) ABSTRACT

A battery pack monitoring system for monitoring a plurality of battery modules within a battery pack. Primary monitoring circuits are coupled to monitor respective battery modules and have circuitry to output measurement values that correspond to the respective battery modules. At least one standby monitoring circuit is coupled to monitor at least one of the battery modules and includes circuitry to output a first measurement value that corresponds to the battery module. A pack controller selectively applies, in a determination of battery pack status, either the first measurement value from the standby monitoring circuit or a second measurement value from one of the primary monitoring circuits.

### CROSS-REFERENCE TO RELATED APPLICATIONS

This application claims priority to, and hereby incorporates by reference, U.S. Provisional Applications No. 61/029,300, No. 61/029,296, and No. 61/029,302, filed on Feb. 15, 2008.

### FIELD OF THE INVENTION

The present invention relates to battery systems.

### BACKGROUND

To achieve higher capacity and energy density in battery-powered automotive and industrial applications, battery packs having a large number of small-form-factor battery cells have been proposed. One draw back of such high cell-density battery packs is that if any one of the many cells (or groups of cells) fails, the entire battery pack may fail. Worse, unless reliably and promptly detected, such cell failure may present a fire hazard or other risk of substantial damage or injury to the system and its operator.

### BRIEF DESCRIPTION OF THE DRAWINGS

The present invention is illustrated by way of example and not limitation in the figures of the accompanying drawings and in which like reference numerals refer to similar elements and in which:

FIG. 1 illustrates an exemplary battery pack that may be employed within a fault-tolerant battery system according to various embodiments;

FIG. 2 illustrates several subsystems that may be included within a fault-tolerant battery system according to one embodiment;

FIG. 3 illustrates one embodiment of a fault-tolerant battery management system that provides a standby subsystem for each active subsystem;

FIG. 4 illustrates one embodiment of a fault-tolerant HVDC controller;

FIG. 5 illustrates another embodiment of a fault-tolerant HVDC controller;

FIG. 6 illustrates the details of the links between each module controller and the respective battery module for the fault-tolerant battery management system shown in FIG. 3;

FIG. 7 illustrates an exemplary sequence of operations carried out by each active module controller and standby module controller, repeated as a loop;

FIG. 8 illustrates an exemplary sequence of operations carried out by each active pack controller and standby pack controller on regular intervals;

FIG. 9 shows one embodiment of an fault-tolerant battery system with N+1 module controller redundancy.

### DETAILED DESCRIPTION

An intelligent fault-tolerant battery management system (IFTBS) for reliably and promptly detecting battery cell failure and thus enabling automatic or operator-directed corrective action is disclosed in various embodiments herein. In embodiments herein, a rechargeable battery system having numerous (e.g., nearly a hundred or more) blocks of interconnected battery cells has respective interconnects between the cell-blocks and battery management circuitry. The rechargeable battery system may be subjected to extreme or otherwise demanding environmental conditions, particularly in automotive or industrial applications in which mechanical strain, vibration and alternating exposure to heat and cold may stress components and interconnections alike. To avoid single point of failure that may imply failure of the entire battery system, redundant connections between the cell-blocks and the battery management circuitry, redundant connections between the cell-blocks and power-delivery circuitry, one or more redundant functional components within the battery management circuitry, and/or one or more redundant components within the power-delivery circuitry is/are provided to avoid false determination of battery system failure.

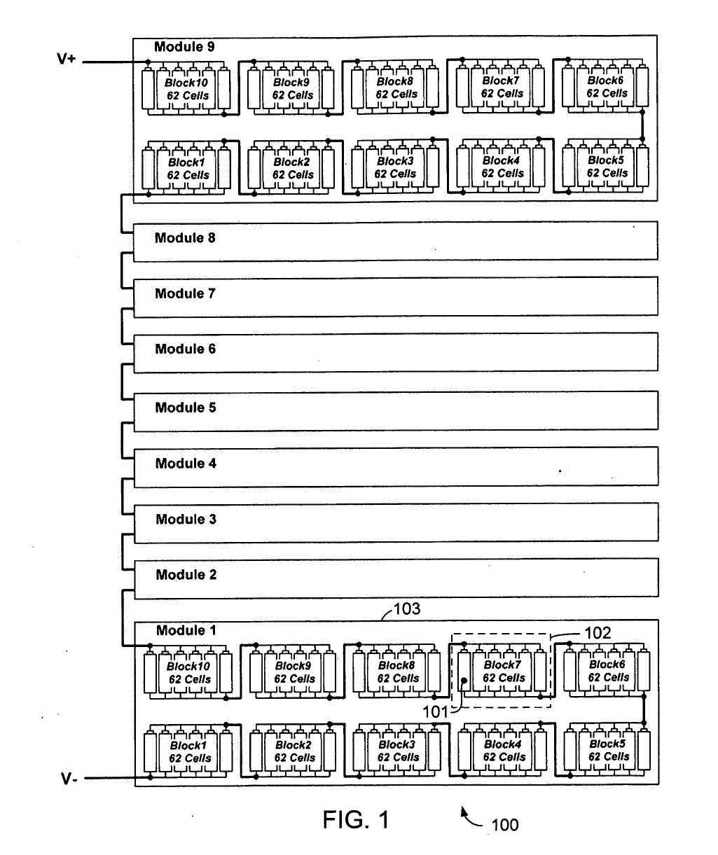

FIG. 1 shows an embodiment of a battery pack 100 having a large number of small form-factor rechargeable battery cells and that constitutes an example of a rechargeable multi-cell battery pack that may be employed in a battery system according to embodiments disclosed below. In this embodiment, cells 101 are grouped into blocks 102 which are grouped, in turn, into modules 103. In the example shown in FIG. 1, each pack comprises 9 modules; each module comprises 10 blocks; and each block comprises 62 cells. Therefore, there are a total of 5580 cells in a pack. Each cell has a positive and a negative terminal, called a cathode and an anode, respectively. In this embodiment, the cells in each block are electrically connected in parallel, i.e., the cathodes are connected together, and the anodes are connected together. The blocks in each module are connected in series, i.e., the cathode of the first block is connected to the anode of the second block, the cathode of the second block is connected to the anode of the third block, and so on and so forth. In addition, the modules are also connected in series. The total voltage potential at the output terminals of the pack (V+, V−) is the voltage at the cathode of the last block of the last module (module number 9, block number 10 in the example shown in FIG. 1, V+) relative to the anode of the first block of the first module (V−). Therefore, the total voltage of a pack is equal to the voltage potential of each block times the number of blocks in each pack. In alternative embodiments, more or fewer battery cells per block, blocks per module or modules per pack may be provided, and interconnection of cells, blocks and modules may be different from the interconnection arrangement shown.

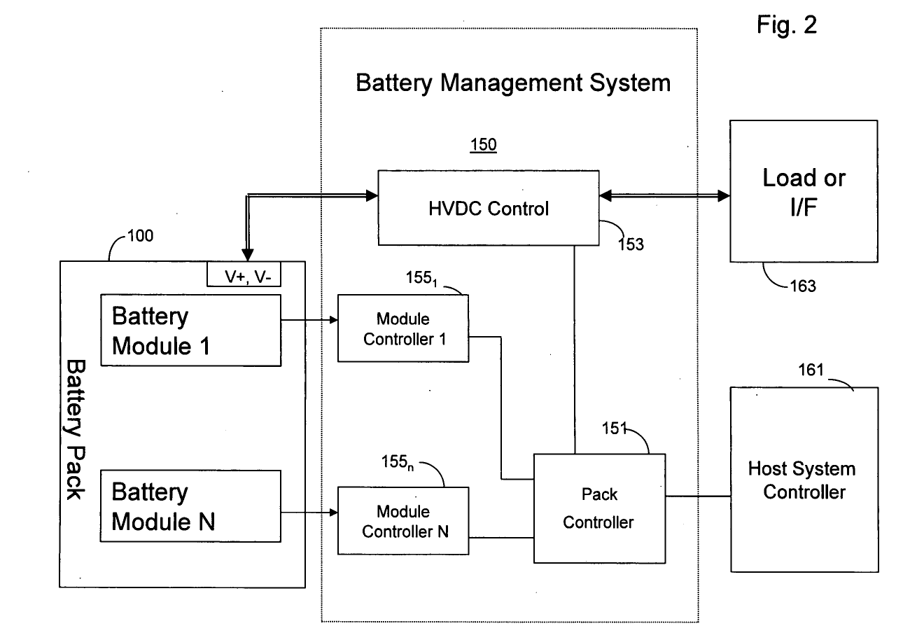

The operation of a battery pack is controlled by a battery management system. FIG. 2 shows one embodiment of a fault-tolerant battery management system 150 that comprises several subsystems, any or all of which may be singly or multiply redundant either in circuitry, interconnection to control/monitor points (or other battery management system components) or both. As an example, and without limitation, the battery management system includes a high voltage direct current (HVDC) controller 153, a pack controller 151, and a plurality of module controllers (alternatively referred to herein as module monitoring circuits) 155₁-155ₙ. The HVDC controller is where the power of the battery is delivered to the external system, as well as where the power to charge the battery is delivered. The pack controller 151 is the main controller that controls the operation of the entire battery system. It also interfaces with an external system that uses the battery pack, such as a vehicle 163. Each module controller monitors and controls the state of charge of the respective battery module in conjunction with the pack controller. Each module controller also monitors the environment of the cells in each module, such as temperature, tilting, and whether excessive moisture and smoke are present.

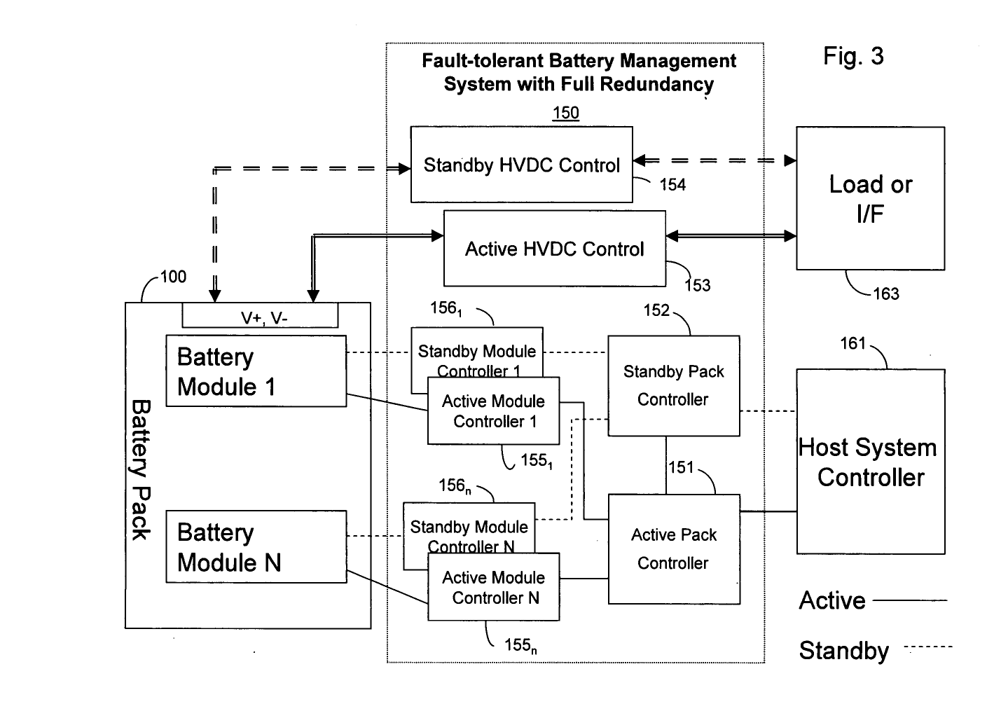

FIG. 3 illustrates a more detailed view of the fault-tolerant battery system of FIG. 2, showing an example of redundant circuit arrangements and interconnections within the battery management system. The fault-tolerant battery management system 150 provides a standby subsystem for each active subsystem (an active subsystem is alternatively referred to herein as a primary subsystem). Also, the links that interface each subsystem with a battery pack and with an external system are also duplicated. In normal operation, the active subsystem performs all the tasks. Upon detection of a failure in an active subsystem or in an active link, the standby subsystem takes over the operation.

### HVDC Control and HVDC Link Redundancy

In one embodiment, the HVDC control includes a high-current primary switch (e.g., a contactor), coupled in parallel with a pre-charge circuit, both controlled by the pack controller 151 via control links (not shown in FIG. 3 to avoid obscuring the depicted connections). The pre-charge circuit itself may include, for example, a pre-charge switch (e.g., a coil- or otherwise-actuated relay, or a transistor switch), and a current limiting device (e.g., a resistor, a coil, or an active current-limiting circuit). In operation, the pre-charge switch is turned on first. When an external voltage is close to the battery voltage, the primary switch is turned on.

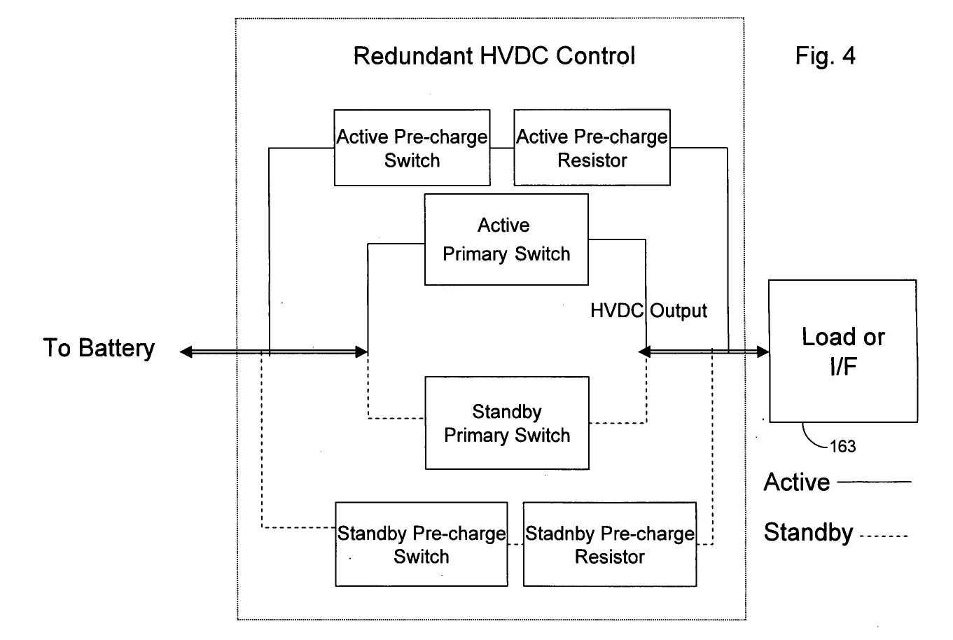

Compared to a typical system where the battery management system provides only one HVDC control and one HVDC interface with a battery pack and external system, a fault-tolerant battery management system provides two (or more) HVDC controls, as well as two (or more) HVDC interfaces, as shown in the embodiment of FIG. 4, thereby providing HVDC control and HVDC link redundancy. In the event the active HVDC interface fails, the standby HVDC interface will be activated and the active HVDC control is also switched to the standby HVDC control. Similarly, if a failure in the active HVDC control is detected the pack controller will switch the function of active HVDC control to standby HVDC control. The links that interfaces the HVDC controller with the battery pack and with an external system are also duplicated. In the event any of the active components or any of the active links fails, the standby components and standby links will be activated.

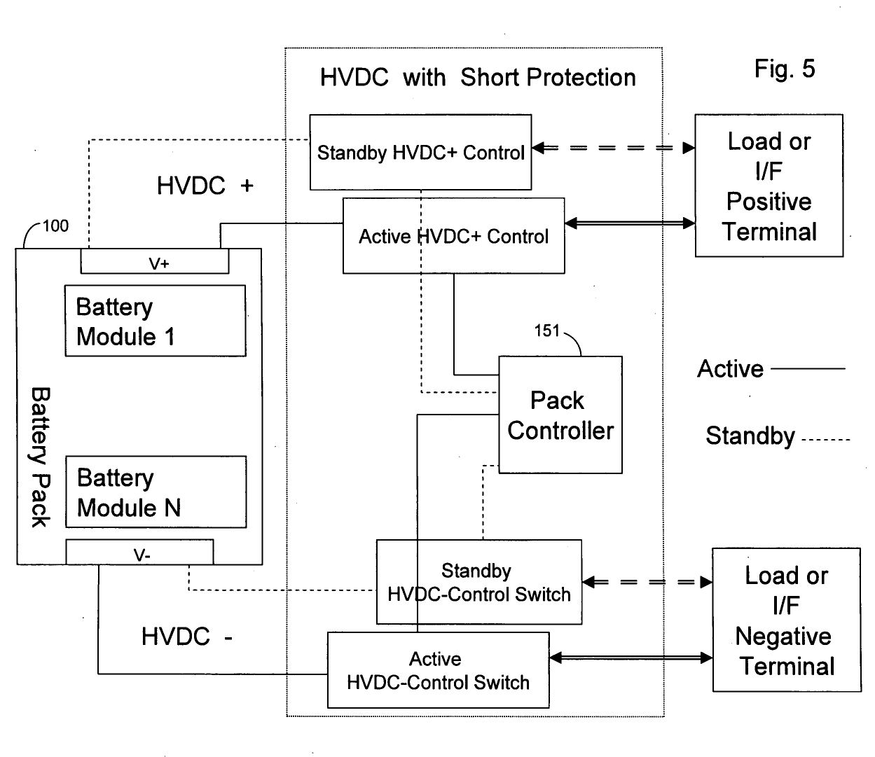

To prevent HVDC control failure due to short circuit, another set of active and standby HVDC controls can be disposed at the negative side of the battery pack, as shown in FIG. 5.

### Pack Controller and Management Interface Redundancy

The fault-tolerant battery system also provides protection against pack controller failure. The active pack controller (alternatively referred to herein as primary pack controller) and standby pack controller maintains a communication link to coordinate their operations; synchronizing their states and detecting any failure. The pack controller has built-in self check and provides a mechanism to release control to the standby controller 152 when it fails the self check. The standby pack controller can also assume control when it detects that the active controller is no longer functioning. The links between the pack controller and the module controllers, referred to herein as management interface, are also duplicated. In the event of a failure in any of the active management interface, the standby pack controller will take control and utilize the standby management interface to continue the operation of the battery system.

### Full Module Controller and Link Redundancy

The fault-tolerant battery management system shown in FIG. 3 provides full module controller redundancy in that there is a standby module controller for each active module controller (alternatively referred to herein as primary monitoring circuit). In normal operation, each active module controller 155₁-155ₙ monitors the status and controls the operation of each respective battery module in conjunction with the pack controller, including the various parameters of the battery modules and balancing of battery modules during charge. In one embodiment, each standby module controller 156₁-156ₙ also monitors the status of each respective battery module, but does not necessarily control the operation of the respective battery module in standby mode. When the pack controller 151 detects a fault in an active module controller, the pack controller may disable the active module controller and activate the corresponding standby module controller.

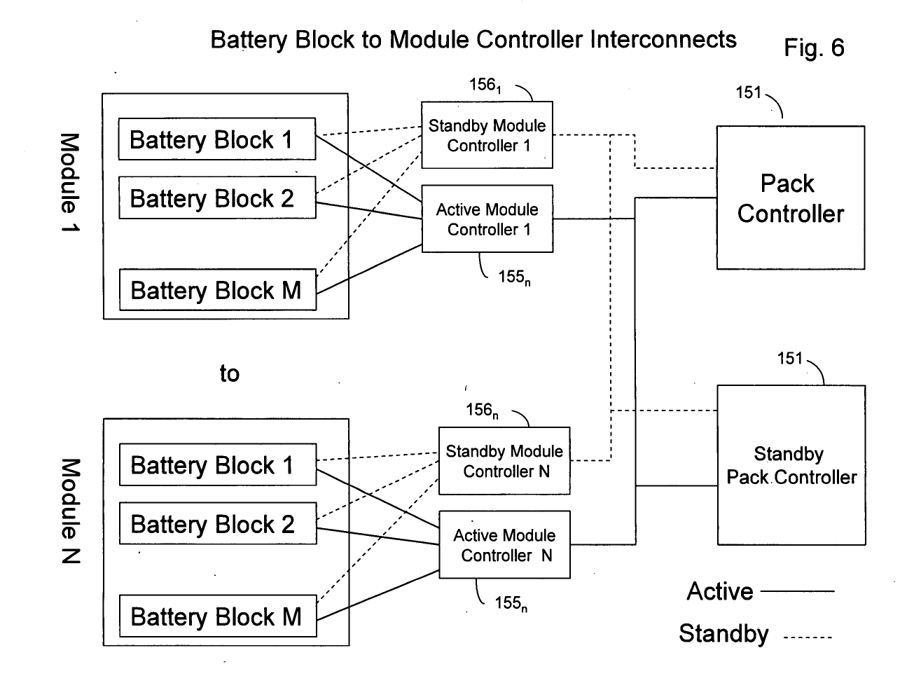

As described above, each battery module may comprise a plurality of blocks. Each module controller monitors the status and controls the operation of each block in the respective battery module. Therefore, there is a plurality of links that interface each module controller with a plurality of blocks. In one embodiment of a fault-tolerant battery system, each link is also duplicated as shown in FIG. 6. When a fault is detected in any of the plurality of active links that interfaces an active module controller with the respective module, the pack controller disables the corresponding active module controller 155 and actives the standby module controller 156.

### Module Controller Operation

Each module controller monitors the status of the blocks in each respective module by measuring a number of parameters, such as voltage, current, temperature, and other environmental parameters. Each module controller reports data to the pack controller periodically, for example, every 100 msec. If any of the parameters is outside a predefined or programmed range, the pack controller may determine the module controller to be faulty by verifying that the value of the same parameter measured by the corresponding standby module controller is within the predefined or programmed range. Each active module controller may also perform a self test periodically or in response to an out-of-range detection or other fault-indicating event.

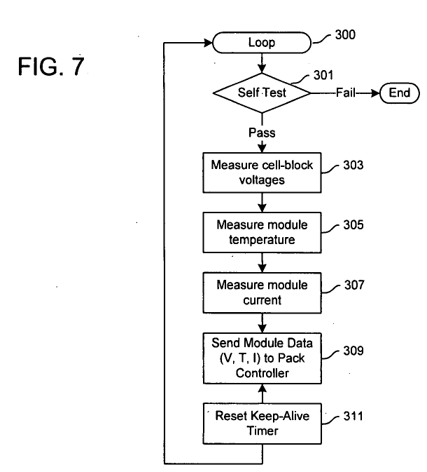

FIG. 7 illustrates an exemplary sequence of operations carried out by each active module controller and standby module controller, repeated as a loop (300) on regular intervals (e.g., 100 times per second, though the loop frequency may be higher or lower in alternative embodiments). Initially, the module controller executes a qualifying self-test at 301 to confirm that the controller circuitry itself is operational. If self-test fails, the module controller process may be halted as shown, optionally sending one or more fault messages to the pack controller or host system controller, indicating that the module controller has failed (including the nature of the failure) and/or that a module-controller reset or system reset may be needed. In an alternative embodiment, or depending on the nature of the failure and/or instruction from the pack controller, the module controller may repeat the self test and/or proceed with remaining operations in the sequence despite the failing self-test result.

If self-test passes or the module controller otherwise determines (or is directed) to proceed with the operational sequence, the module controller measures the voltages of each block of cells within the corresponding battery module at 303, measures the battery module temperature at 305, and measures the battery module charge current or discharge current at 307. More or fewer parameters of module health or status, and/or environment may be measured in alternative embodiments. In one implementation, the module controller makes no out-of-range or other fault or warning determination, but rather merely sends the measured parameters (voltage(s), current(s), temperature(s), (V, T, I) in this embodiment) to the pack controller as shown at 309. In alternative embodiments, the module controller may additionally make such out-of-range/fault determinations by comparing the measured data to predetermined, dynamically-determined, and/or programmed thresholds. The module controller may also perform a filtering or other statistical function with respect to the measured data. Further, the module controller may not send measurement data to the pack controller on every pass through the operational loop shown, but rather only upon detecting out-of-range in one or more parameters or only once for every n loop iterations (where n>1). Finally, in one embodiment, the module controller may reset a fail-safe or “keep-alive” timer circuit as shown at 311 to indicate that the module controller is operational. That is, the fail-safe timer circuit indicates that the module controller is operational unless reset within a predetermined or programmatically determined interval and thus provides an alternative manner for the pack controller to determine failure (or confirm operational status) of a module controller.

### Pack Controller Operation

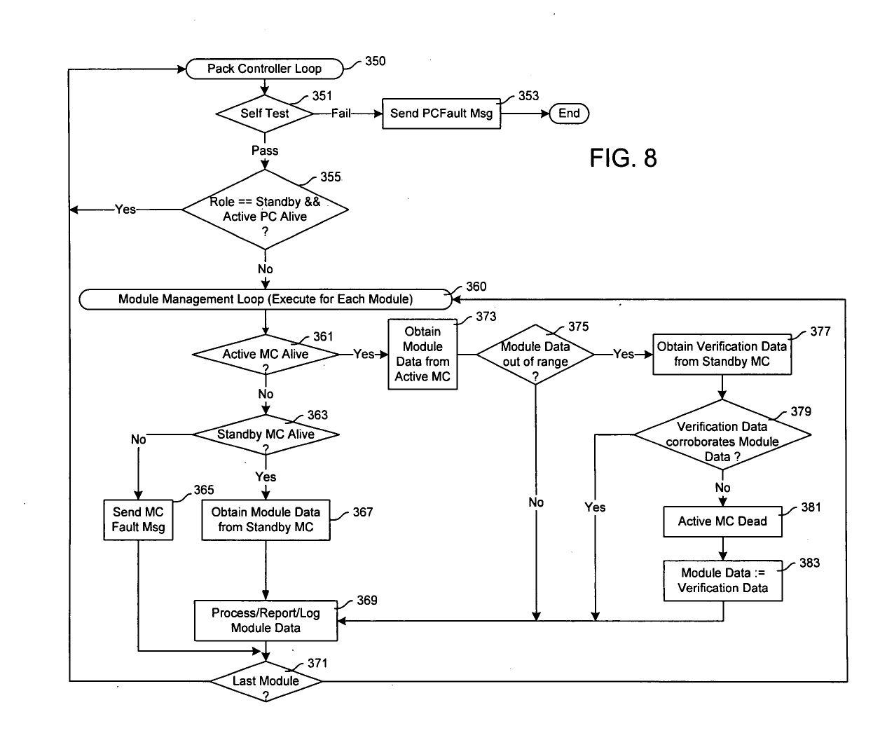

FIG. 8 illustrates an exemplary sequence of operations carried out by each active pack controller and standby pack controller on regular intervals (e.g., 10 times per second, though the loop frequency may be higher or lower in alternative embodiments). Starting from the head of the pack controller loop at 350, the pack controller executes a self-test at 351 to confirm that the pack-controller circuitry itself is operational. If self-test fails, the pack controller process may be halted, optionally sending one or more fault messages (353) to the host-system controller (e.g., to a vehicle controller via a vehicle battery management interface as discussed in reference to FIG. 3), indicating that the pack controller has failed (including the nature of the failure) and/or that a pack-controller reset or system reset may be needed. In an alternative embodiment, or depending on the nature of the failure and/or instruction from the host controller, the pack controller may repeat the self test and/or proceed with remaining operations in the sequence despite the failing self-test result.

In one embodiment, if self-test passes or the pack controller otherwise determines (or is directed) to proceed with the operational sequence, the pack controller proceeds with additional pack-control functions upon determining at 355 that either (i) it is not the standby pack controller or (ii) the active pack controller is not operational (the latter shown by “Active PC Alive” in decision 355). That is, if the pack controller executing the operational flow shown in FIG. 8 is the standby pack controller (determined, for example, by jumpering, non-volatile programming, and/or run-time instruction from the host controller) and the active pack controller is alive (i.e., not disabled or otherwise known or deemed to be inoperable or defective), the pack controller continues looping on the self-test operation (351). Otherwise, if the pack controller is the active pack controller (or is the standby pack controller and the active pack controller is dead), the pack controller proceeds to execution of the module management loop at 360.

In one embodiment, the module management loop is executed once for each battery module before returning to the start of the pack controller loop. In an alternative embodiment, the module management loop (or module management sequence) may be executed once per pack controller loop, incrementing from module to module with each pack-controller loop iteration. In either case, in the embodiment of FIG. 8, the pack controller begins the module management loop (or sequence) by determining the operational status of the active module controller for the battery module under evaluation (the “subject battery module”). If the active module controller is disabled, inoperable or otherwise not functioning properly (i.e., “dead” or not “alive” as determined at 361), then the standby module controller status is evaluated at 363. If the standby module controller is also dead, the pack controller sends a module-controller (“MC”) fault message for the subject battery module to the host controller at 365. Thereafter, assuming an embodiment in which all battery modules are evaluated once per pack controller loop, the pack controller determines if the subject battery module is the last module to be evaluated at 371. If not, the pack controller repeats the module management loop 360 for the next battery module. If the subject battery module is the last module to be evaluated, the pack controller returns to the start of the pack control loop 350.

Returning to decision 361, if the active module controller is alive, then module data is obtained from the active module controller at 373 (e.g., by polling or otherwise querying the active module controller or by retrieving a message containing the module data from a buffer or other predetermined storage location within or external to the pack controller). The module data may include any number of operational status parameters, including the cell-block voltages, temperature, current described in reference to the module controller of FIG. 7. At 375, the pack controller compares the module data to predetermined, dynamically determined and/or programmed thresholds to determine whether any of the module data is out of range. If none of the module data is out of range, then at 369 the pack controller processes the data as necessary (e.g., filtering, integrating or otherwise combining the information in calculation or computation of additional values such as total power consumed or total discharge rate), reports the module data to the host controller (e.g., for presentation to a user, to drive alarms or alerts, to make operational decisions, etc.), and/or logs the module data or derivation from the module data in a database for later retrieval. Thereafter, the module controller proceeds to decision block 371, continuing the module management loop if data from the last of the multiple battery modules has not been processed.

Returning to decision 375, if the module data is determined to be out of range in one or more respects, the pack controller proceeds to obtain corresponding module data from the standby module controller for verification purposes. Though not specifically shown, the pack controller may first confirm that the standby module controller is alive before obtaining module data therefrom. Continuing, the pack controller obtains module data from the standby module controller (“Verification Data”) at 377, then determines whether the verification data corroborates the out-of-range condition indicated by the active module controller (i.e., indicated by the “Module Data”) at 379. If so, the out-of-range condition is deemed verified, and the pack controller proceeds to process/report/log the data, including any out-of-range data therein, at 369. If the verification data does not corroborate the out-of-range indication (negative determination at decision 379), then the pack controller may deem the data from the active module controller to be unreliable. In the embodiment shown in FIG. 8, for example, the pack controller may designate the active module controller to be dead (or at least no longer alive for purposes of the decision at 361) and then replace, overwrite or otherwise proceed with the process/report/log operation using the in-range module data from the standby module controller instead of the out-of-range data from the formerly active module controller. This is shown in FIG. 8 by the assignment of the verification data to the module data at 383. Returning to 381, the pack controller may additionally take action to prevent the suspect active module controller from causing system disruption by affirmatively disabling the active module controller, including switchably decoupling the suspect module controller from one or more monitoring points.

Returning to decisions 361 and 363, if the active module controller is not alive, and the standby module controller is alive, the pack controller may obtain module data from the standby pack controller at 367 (i.e., as described in reference to 373) and then proceed to the process/report/log operation(s) at 369.

### Partial Module Controller Redundancy

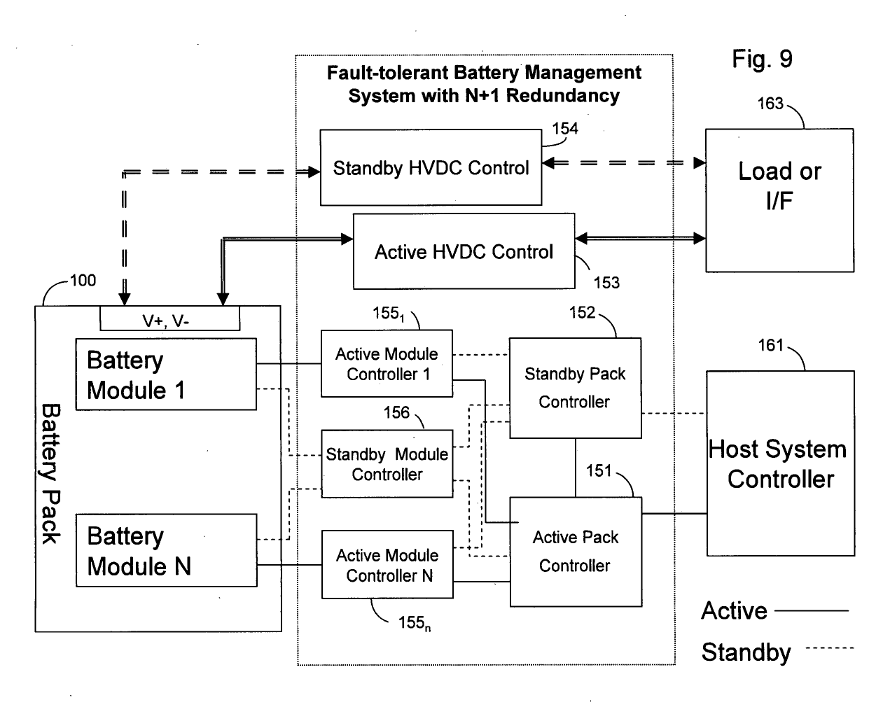

In the N+1 module controller redundancy as depicted in FIG. 9, the system provides only one or a few standby module controller for the entire battery system. The standby module controller will not monitor the battery status while in standby, but instead upon detection of a failure in a particular module controller, the standby module controller will be switched to monitor and control the battery module where the module controller has failed. Prior to switching, the pack controller will load the state of battery module needed into the standby module needed into the standby module controller.

FIG. 9 shows one embodiment of a fault-tolerant battery system with N+1 module controller redundancy. In this system, only one standby module controller 156 is provided for the entire set of module controllers, (or at least fewer standby module controllers than the number of battery modules to be controlled), and it is interfaced with each battery module (i.e., switchably or directly coupled to all or a subset of the monitoring nodes for each battery module). In one embodiment, the standby module controller does not monitor the status of each battery module while in standby mode. When a failure in one of the active module controllers is detected, the standby module controller is switched to monitor and control the corresponding battery module. Prior to switching, the pack controller may load the state of the corresponding battery module into the standby module controller. The pack controller may also disable the faulty active module controller. In an alternative embodiment, the standby module controller may monitor all the battery modules and provide data for each module to the pack controller for comparison with corresponding data received from the primary module controller, thereby enabling fault detection with respect to each primary module controller. For example, if the data from a primary module controller indicates an out-of-range condition that is not corroborated by the standby module controller (i.e., measurement data from the standby module controller does not indicate the out-of-range condition), the primary module controller may be deemed defective and data from the standby module controller used instead of that from the primary module controller to determine module health, perform power consumption calculations and so forth.

In alternative embodiments, other partial module controller redundancy modes, which use two or more standby module controllers, can be used, wherein each standby module controller is capable of standing in for any of the active module controllers (or even for another standby module controller, thereby providing double-redundancy), or for a respective subset of the active module controllers.

### Single Link Configuration

In alternative embodiments, a fault-tolerant battery management system may be used with an external system that provides only one interface. In one such embodiment, for example, the fault-tolerant battery management system may have only one interface link between the active pack controller and the external system, but also have a link between the active and standby pack controller. If a failure is detected in the active pack controller, the standby pack controller takes over the operation and interfaces with the external system via the external link and disables the formerly active pack controller. Alternatively, the single external interface may be connected to interfaces for both the active and standby pack controllers.

Similarly, a fault-tolerant battery management system may have only one interface link between the active HVDC control and the external system, but also have a link between the active and standby HVDC controls. If a failure is detected in the active HVDC control, the standby HVDC control takes over the operation and interfaces with the external system via the link with the superseded (formerly active) HVDC control.

### Fail-Safe Mechanism

The various fault-tolerant battery system embodiments described herein may utilizes several different fail-safe mechanisms including, without limitation, peripheral diagnostic, self diagnostic, watch dog timer, heart beat, etc. As an example, a one-shot relay or like circuit which will switch between closed and open states if not pulsed, signaled, charged or otherwise attended to within a predetermined interval may be provided to establish a fail-safe shutdown in the event of catastrophic failure of any subsystem.

In the foregoing description and in the accompanying drawings, specific terminology and drawing symbols have been set forth to provide a thorough understanding of the present invention. In some instances, the terminology and symbols may imply specific details that are not required to practice the invention. For example, any of the specific numbers of bits, signal path widths, signaling or operating frequencies, component circuits or devices and the like may be different from those described above in alternative embodiments. Additionally, the interconnection between circuit elements or blocks may be shown as buses or as single signal lines. Each of the buses may alternatively be a single signal line, and each of the single signal lines may alternatively be buses. Signals and signaling paths shown or described as being single-ended may also be differential, and vice-versa. A signal driving circuit is said to “output” a signal to a signal receiving circuit when the signal driving circuit asserts (or deasserts, if explicitly stated or indicated by context) the signal on a signal line coupled between the signal driving and signal receiving circuits. The term “coupled” is used herein to express a direct connection as well as a connection through one or more intervening circuits or structures. Device “programming” may include, for example and without limitation, loading a control value into a register or other storage circuit within the device in response to a host instruction and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The terms “exemplary” and “embodiment” are used to express an example, not a preference or requirement.

While the invention has been described with reference to specific embodiments thereof, it will be evident that various modifications and changes may be made thereto without departing from the broader spirit and scope. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

What is claimed is:

1. A battery pack monitoring system for monitoring a plurality of battery modules within a battery pack, each of the battery modules to include one or more battery cells, the battery pack monitoring system comprising:
a plurality of primary monitoring circuits coupled respectively to monitor a plurality of battery modules and having circuitry to output measurement values that correspond to respective battery modules;
at least one standby monitoring circuit coupled to monitor at least one of the battery modules and having circuitry to output a first measurement value that corresponds to the at least one of the battery modules; and
a first pack controller to selectively apply, in a determination of battery pack status, either the first measurement value from the standby monitoring circuit or a second measurement value from one of the primary monitoring circuits coupled to the at least one of the battery modules.

2. The battery pack monitoring system of claim 1 wherein the one or more battery cells comprise re-chargeable battery cells.

3. The battery pack monitoring system of claim 1 wherein the pack controller comprises circuitry to enable the at least one standby monitoring circuit to monitor the at least one of the battery modules in response to an indication that the second measurement value from the one of the primary monitoring circuits may be unreliable.

4. The battery pack monitoring system of claim 3 wherein the indication that the second measurement value from the one of the primary monitoring circuits may be unreliable comprises a self-test result reported from the one of the primary monitoring circuits to the pack controller.

5. The battery pack monitoring system of claim 3 wherein the indication that the second measurement value from the one of the primary monitoring circuits may be unreliable comprises an out-of-range indication within the second measurement value.

6. The battery pack monitoring system of claim 5 wherein the pack controller comprises circuitry to compare the second measurement value with the first measurement value and, if the first measurement value does not corroborate the out-of-range indication within the second measurement value, to select the first measurement value to be applied in the determination of battery pack status instead of the second measurement.

7. The battery pack monitoring system of claim 1 wherein the pack controller includes circuitry to apply the second measurement value in the determination of battery pack status absent indication that the second measurement value may be unreliable.

8. The battery pack monitoring system of claim 1 wherein the at least one standby monitoring circuit is coupled to monitor a plurality of the battery modules.

9. The battery pack monitoring system of claim 1 wherein the at least one standby monitoring circuit is coupled to monitor all the battery modules.

10. The battery pack monitoring system of claim 1 further comprising a plurality of additional standby monitoring circuits coupled to other ones of the respective battery modules, and wherein the pack controller selectively applies, in the determination of battery pack status, either a measurement value from the additional standby monitoring circuit or a measurement value from another one of the primary monitoring circuits.

11. The battery pack monitoring system of claim 1 wherein the pack controller comprises circuitry to compare the first measurement value to the second measurement value, and to apply the first measurement value in the determination of battery pack status if the second measurement value indicates an out-of-range condition that is not corroborated by the first measurement value.

12. The battery pack monitoring system of claim 1 further comprising a second pack controller to determine the battery pack status in response to an indication that the first pack controller may be unreliable.

13. The battery pack monitoring system of claim 1 further comprising:
primary high voltage direct current (HVDC) control circuitry controlling delivery of power to an external system or delivery of power or to charge the battery pack; and
standby HVDC control circuitry to control the delivery of power in response to an indication that the primary HVDC control circuitry may be unreliable.

14. The battery pack monitoring system of claim 1 wherein the first measurement value comprises an output voltage of the one of the battery modules.

15. The battery pack monitoring system of claim 1 wherein the determination of battery pack status comprises an estimation of battery capacity remaining within the battery pack.

16. A method of controlling a battery pack having a plurality of battery modules, the method comprising:
outputting respective measurement values from each of a plurality of primary monitoring circuits coupled respectively to monitor the plurality of battery modules;
outputting a first measurement value from a standby monitoring circuit coupled to monitor at least one of the plurality of battery modules; and
selecting, for application in a determination of battery pack status, either the first measurement value from the standby monitoring circuit or a second measurement value from one of the primary monitoring circuits coupled to the at least one of the battery modules.

17. The method of claim 16 further comprising determining the battery pack status based at least in part on the first measurement value if the second measurement value is indicated to be unreliable, and determining the battery pack status based at least in part on the second measurement value if the second measurement value is not indicated to be unreliable.

18. The method of claim 16 wherein selecting either the first measurement value or the second measurement value comprises selecting the first measurement value to be applied in the determination of battery pack status if the second measurement value indicates an out-of-range condition that is not corroborated by the first measurement value.

19. The method of claim 17 further comprising enabling the standby monitoring circuit to monitor the one of the battery modules and output the first measurement value in response to an indication that the second measurement value may be unreliable.

20. A battery monitoring apparatus for monitoring status of a plurality of battery modules, the battery monitoring apparatus comprising:
means for outputting respective measurement values from each of a plurality of primary monitoring circuits coupled respectively to monitor the plurality of battery modules;
means for outputting a first measurement value from a standby monitoring circuit coupled to monitor at least one of the plurality of battery modules; and
means for selecting, for application in a determination of battery pack status, either the first measurement value from the standby monitoring circuit or a second measurement value from one of the primary monitoring circuits coupled to the at least one of the battery modules.
